(19) United States
(12) Patent Application Publication
(10) Pub. No.: US 2025/0254811 A1
(43) Pub. Date: Aug. 7, 2025

(54) BOX-SHAPED BODY

(71) Applicant: YAZAKI CORPORATION, Tokyo (JP)

(72) Inventors: Ayumu Kurizono, Makinohara-shi (JP); Tsukasa Saito, Makinohara-shi (JP); Etsurou Takai, Makinohara-shi (JP); Toshihisa Yagi, Tokyo (JP); Yuta Masuda, Tokyo (JP)

(21) Appl. No.: 19/031,192

(22) Filed: Jan. 17, 2025

(30) Foreign Application Priority Data
Feb. 5, 2024 (JP) 2024-015501

(51) Int. Cl. H05K 5/03; H02G 3/14

(52) U.S. Cl. CPC H05K 5/03; H02G 3/14

(57) ABSTRACT

A box-shaped body includes: a case having a tubular peripheral wall; and a cover assembled to the peripheral wall to cover an opening end of the case. The cover includes a plurality of engaging portions extending in an attachment direction in which the cover is attached to the case. The case includes a plurality of engaged portions configured to be engaged with the engaging portions, respectively. Each of the plurality of engaged portions includes a guide portion configured to guide the engaging portion toward an engaged structure configured to be engaged with the engaging portion. At least one of the plurality of engaging portions has a length longer than a length of another engaging portion in the attachment direction, and is guided by the guide portion of the engaged portion prior to the other engaging portion when the case and the cover are assembled.

### CROSS-REFERENCE TO RELATED APPLICATION(S)

This application is based upon and claims the benefit of priority from prior Japanese patent application No. 2024-015501 filed on Feb. 5, 2024, the entire contents of which are incorporated herein by reference.

### BACKGROUND

### 1. Field of the Invention

The present disclosure relates to a box-shaped body including a case that has a peripheral wall surrounding an internal space, and a cover that is assembled to an opening end of the case.

### 2. Description of the Related Art

In the related art, a box-shaped body configured by assembling a plurality of members to each other, such as an electric junction box (for example, a relay box) mounted on a vehicle, has been proposed. For example, an electric junction box in the related art includes a body case that holds an electronic component and the like, and a cover that is assembled to the body case. In this electric junction box, the cover is assembled to be fitted to the body case (for example, see JP2001-185869A).

In the electric junction box in the related art described above, the cover and the case are assembled by engaging, with the case, a plurality of engaging portions (for example, lock claws) provided on the cover. However, in order to collectively engage the plurality of engaging portions, an operator assembles the cover and the case while visually checking whether all the engaging portions are in proper lock positions. Such an operation is a factor that hinders improvement in operability of the operation of assembling the cover and the case from being improved. Therefore, it is desirable to reduce such checking operation as much as possible. As understood from the above description, it is desirable to improve operability of an assembly operation in a box-shaped body including a cover and a case, not limited to the electric junction box.

### SUMMARY

An object of the present disclosure is to provide a box-shaped body capable of improving operability of an assembly operation.

In order to achieve the above object, a box-shaped body according to the present disclosure is characterized as follows.

According to an aspect of the present disclosure, there is provided a box-shaped body including: a case having a tubular peripheral wall; and a cover assembled to the peripheral wall to cover an opening end of the case, in which: the cover includes a plurality of engaging portions extending in an attachment direction in which the cover is attached to the case; the case includes a plurality of engaged portions configured to be engaged with the engaging portions, respectively; each of the plurality of engaged portions includes a guide portion configured to guide the engaging portion toward an engaged structure configured to be engaged with the engaging portion; and at least one of the plurality of engaging portions has a length longer than a length of another engaging portion in the attachment direction, and is guided by the guide portion of the engaged portion prior to the other engaging portion when the case and the cover are assembled.

According to the box-shaped body according to the present disclosure, an engaging portion having a longer length in an attachment direction among a plurality of engaging portions is guided by a guide portion of a corresponding engaged portion prior to another engaging portion. Accordingly, after the engaging portion having the longer length is positioned with respect to the engaged portion of the case, the assembly operation can be performed such that the other engaging portion is brought close to the engaged portion of the case. From a viewpoint of improving operability, it is preferable that the engaging portion having the longer length is disposed at a position that is easily seen by an operator. Therefore, the assembly operation becomes easier and the operability of the assembly operation can be improved compared to a case in which all the engaging portions are assembled while being simultaneously positioned.

The present disclosure is briefly described above. Details of the present disclosure can be clarified by reading a mode for carrying out the invention to be described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a perspective view showing a box-shaped body according to an embodiment of the present disclosure;

FIG. 2 is a perspective view showing a state in which an upper cover is being assembled to a body case and a lower cover is separated from the body case in the box-shaped body shown in FIG. 1;

FIG. 3 is a perspective view showing a state in which assembly of the box-shaped body shown in FIG. 1 is completed;

FIG. 4 is a side view of the box-shaped body shown in FIG. 3;

FIG. 5 is a cross-sectional view taken along a line A-A in FIG. 4;

FIG. 6 is a cross-sectional view taken along a line B-B in FIG. 4; and

FIG. 7 is an enlarged view of a portion C in FIG. 4.

### DETAILED DESCRIPTION OF THE INVENTION

### Embodiment

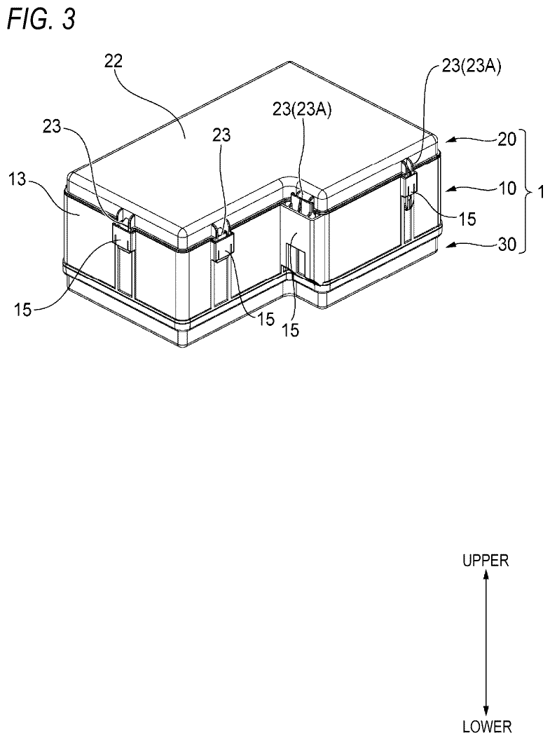

Hereinafter, a box-shaped body 1 according to an embodiment of the present disclosure shown in FIG. 3 will be described with reference to the drawings. The box-shaped body 1 is typically a relay box (electric junction box) that is assembled to a frame or the like of a vehicle and accommodates an electronic component such as a relay.

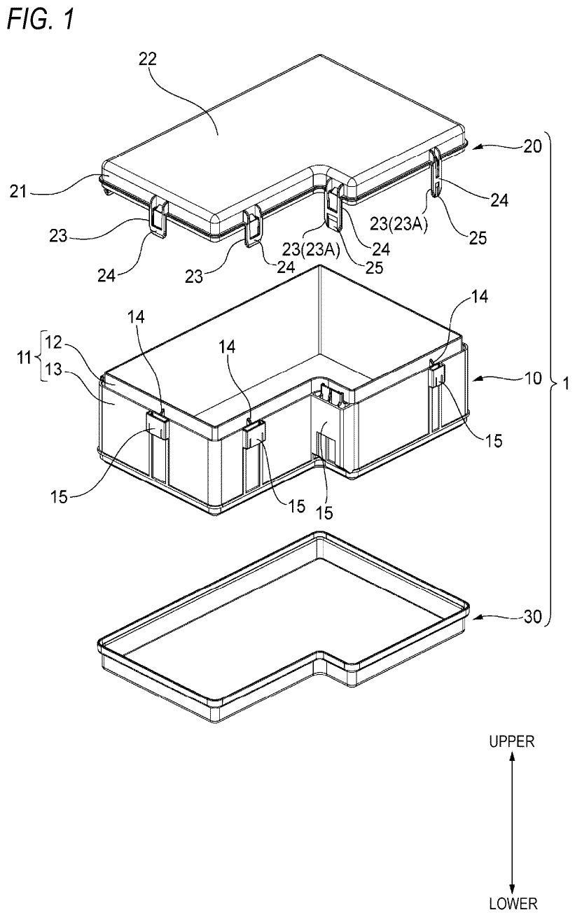

As shown in FIG. 1, the box-shaped body 1 is a box-shaped body including a body case 10, an upper cover 20, and a lower cover 30. The body case 10 accommodates an electronic component such as a relay (and another component that is not shown). The upper cover 20 is assembled to an upper end of the body case 10 to close an upper end opening (opening end) of the body case 10. The lower cover 30 is assembled to a lower end of the body case 10 to close a lower end opening (opening end) of the body case 10. Each of the body case 10, the upper cover 20, and the lower cover 30 is a resin molded body. The body case 10 corresponds to a “case” in the present disclosure. The upper cover 20 corresponds to a “cover” in the present disclosure.

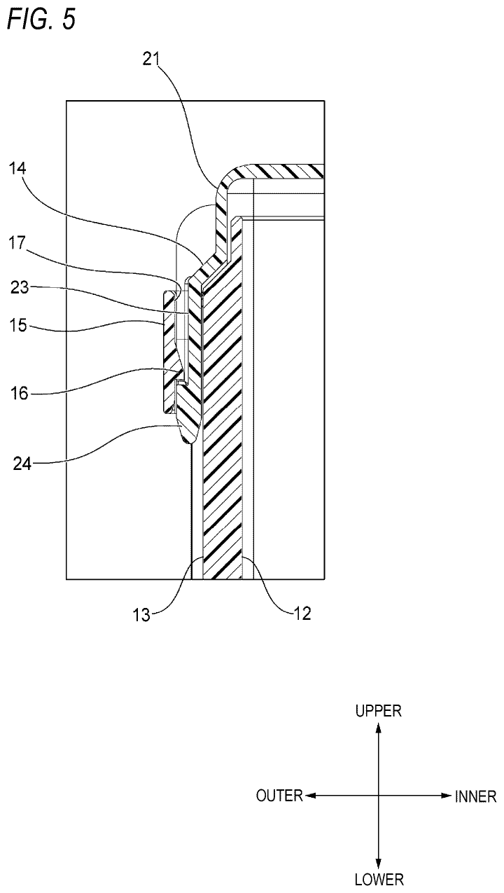

Hereinafter, for convenience of description, a direction of the box-shaped body 1 in a vehicle-mounted posture, which corresponds to an upper-lower direction of a vehicle, is defined as an “upper-lower direction”. A peripheral direction of a peripheral wall 11 of the body case 10 described later is defined as a “peripheral direction”. A thickness direction of the peripheral wall 11 is defined as an “inner-outer direction”. The “upper-lower direction”, the “peripheral direction”, and the “inner-outer direction” are orthogonal to each other (see FIGS. 5 to 7). “Inner” and “outer” of the “inner-outer direction” respectively correspond to inside and outside of the box-shaped body 1 that is a box-shaped body. The “upper-lower direction” is merely defined for convenience of description, and does not necessarily correspond to the upper-lower direction of the vehicle or the like when the box-shaped body 1 is mounted on the vehicle or the like. For example, the box-shaped body 1 may be used in a posture in which the upper cover 20 is located on an upper side or in a posture in which the upper cover 20 is located on a lower side. Hereinafter, the body case 10 and the upper cover 20 constituting the box-shaped body 1 will be described in detail.

First, the body case 10 will be described. As shown in FIG. 1, the body case 10 includes the tubular peripheral wall 11 that has a substantially L shape when viewed in the upper-lower direction and that extends in the upper-lower direction. A plurality of accommodating portions (not shown) accommodating electronic components (and other components) such as a relay are provided in an internal space of the body case 10 defined by the peripheral wall 11. The peripheral wall 11 has a so-called two-layer wall structure including an inner wall 12 and an outer wall 13 over the entire peripheral direction. The outer wall 13 is located outside the inner wall 12 and is spaced apart from the inner wall 12. In this example, an upper end surface of the outer wall 13 is located lower than an upper end surface of the inner wall 12.

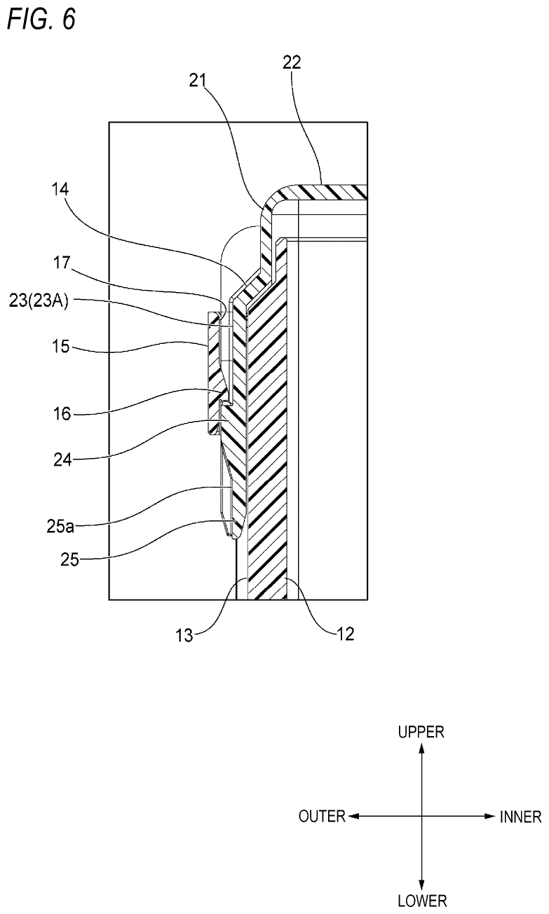

As shown in FIG. 1, an outer surface of an upper end edge of the outer wall 13 that constitutes the peripheral wall 11 is provided with engaged portions 15 at a plurality of positions (eight positions in this example) in the peripheral direction. In a state in which assembly of the body case 10 and the upper cover 20 is completed (see FIG. 3), the plurality of engaged portions 15 are respectively engaged with a plurality of engaging portions 23 that is provided on the upper cover 20 and that is described later. In this example, each of the engaged portions 15 is a substantially rectangular tubular portion which is wide in the peripheral direction and in which a locking hole penetrating in the upper-lower direction is defined. A projection 16 projecting toward inside of the locking hole (that is, toward the inside) is provided at a substantially center position in the upper-lower direction of an outer one of inner wall surfaces that define the locking hole in the engaged portion 15 (see FIGS. 5 and 6). The projection 16 corresponds to an “engaging structure” in the present disclosure. An upper end surface of the engaged portion 15 (that is, an upper opening edge of the locking hole) and the upper end surface of the outer wall 13 are located at the same position in the upper-lower direction. The projections 16 of the plurality of engaged portions 15 are located at the same position in the upper-lower direction. A region that is defined by the inner wall surfaces defining the locking hole in each engaged portion 15 and that is above the projection 16 functions as a guide portion 17 that guides the engaging portion 23 toward the projection 16 (see FIGS. 5 and 6).

As shown in FIG. 1, the peripheral wall 11 is provided with connecting walls 14 at positions in the peripheral direction where the plurality of engaged portions 15 are provided respectively (see also FIGS. 5 and 6). The connecting wall 14 connects layers of the inner wall 12 and the outer wall 13 in the inner-outer direction and extends in the upper-lower direction. In other words, each connecting wall 14 is provided to be adjacent to an inner side of corresponding one of the engaged portions 15. In this example, an upper end surface of the connecting wall 14 is inclined downward (that is, to approach the engaged portion 15 in the upper-lower direction) from the inner wall 12 toward the outer wall 13. As shown in FIG. 1, an outer end of the upper end surface of the connecting wall 14 (a portion connected to the outer wall 13) and the upper end surface of the outer wall 13 are located at the same position in the upper-lower direction, and an inner end of the upper end surface of the connecting wall 14 (a portion connected to the inner wall 12) is located lower than the upper end surface of the inner wall 12.

Next, the upper cover 20 will be described. As shown in FIG. 1, the upper cover 20 integrally includes a tubular peripheral wall 21 and a flat plate-shaped top wall portion 22. The peripheral wall 21 has a substantially L shape corresponding to the peripheral wall 11 of the body case 10 when viewed in the upper-lower direction and extends in the upper-lower direction. The top wall portion 22 closes an upper end opening (opening end) of the peripheral wall 21. An outer surface of the peripheral wall 21 is provided with the engaging portions 23 at a plurality of positions (eight positions in this example) in the peripheral direction corresponding to the plurality of engaged portions 15 of the body case 10. In this example, each engaging portion 23 is a substantially elongated flat plate-shaped portion that extends downward from the outer surface of the peripheral wall 21 in a cantilever shape and that protrudes further downward from a lower end edge of the peripheral wall 21. An outer surface of the engaging portion 23 is provided with a projection 24 that is to be engaged with the projection 16 of the engaged portion 15 of the body case 10. The projections 24 of the plurality of engaging portions 23 are located at the same position in the upper-lower direction.

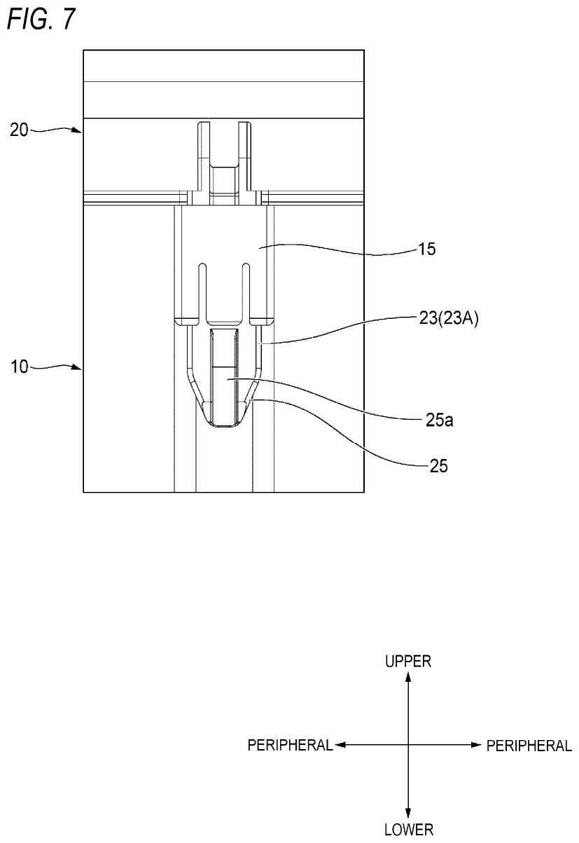

As shown in FIG. 1 and the like, different from the other engaging portions 23, two engaging portions 23A (see FIG. 1 and the like) among the plurality of engaging portions 23 are respectively provided with extending portions 25 (see also FIGS. 5 and 6). The extending portion 25 continuously extends further downward from a position where the projection 24 is provided. Therefore, each of the two engaging portions 23A has a length longer than those of the other engaging portions 23 in the upper-lower direction, and lower end edges of the two engaging portions 23A are located lower than lower end edges of the other engaging portions 23. As shown in FIG. 1 and the like, the two engaging portions 23 A are provided on two surfaces of the peripheral wall 21 of the upper cover 20 which have peripheral directions (surface directions) orthogonal to each other. An operation achieved by locating the lower end edges of the two engaging portions 23A lower than the lower end edges of the other engaging portions 23 will be described later. As shown in FIGS. 6 and 7, a groove portion 25a is formed on an outer surface of the extending portion 25 of one of the two engaging portions 23A to extend in the upper-lower direction. The groove portion 25a guides a tool (not shown) that releases the engagement between the engaging portion 23A and the corresponding engaged portion 15.

Next, the assembly of the body case 10 and the upper cover 20 will be described. In order to assemble the body case 10 and the upper cover 20, first, as shown in FIG. 1, the body case 10 and the upper cover 20 are disposed such that the body case 10 is located below the upper cover 20. Next, the body case 10 and the upper cover 20 are brought close to each other in the upper-lower direction, and an upper end edge of the peripheral wall 11 of the body case 10 and the lower end edge of the peripheral wall 21 of the upper cover 20 are fitted to each other. This fitting proceeds such that the lower end edge of the peripheral wall 21 enters between upper end edges of the inner wall 12 and the outer wall 13 which constitute the peripheral wall 11 and the plurality of engaged portions 15 and the plurality of engaging portions 23 are respectively engaged with each other.

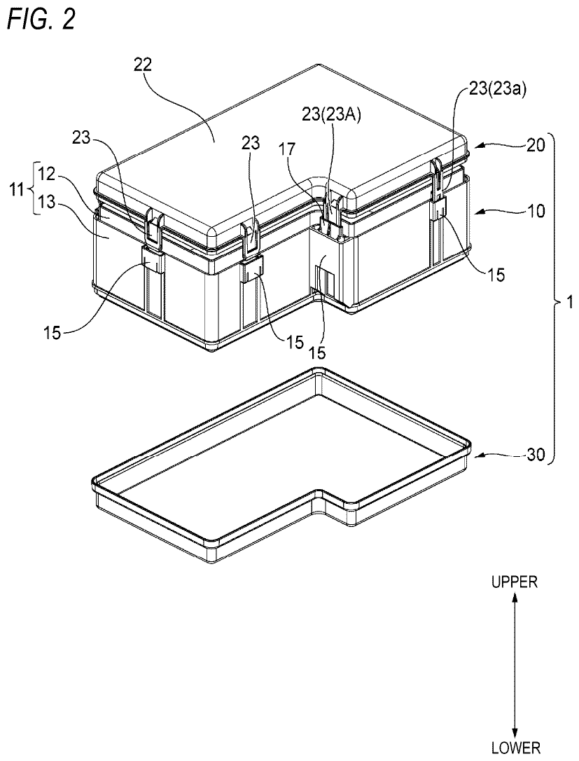

When the fitting proceeds, the lower end edges of the two engaging portions 23A are located lower than the lower end edges of the other engaging portions 23, and thus, as shown in FIG. 2, the lower end edges of the two engaging portions 23A are guided by the guide portions 17 of the engaged portions 15 prior to the lower end edges of the other engaging portions 23. Accordingly, the assembly operation of the upper cover 20 becomes easier by first positioning the upper cover 20 with respect to the body case 10 by the two engaging portions 23A. Since the two engaging portions 23A are provided on the two surfaces of the peripheral wall 21 of the upper cover 20 which have the peripheral directions (surface directions) orthogonal to each other, it is possible to prevent misalignment of the upper cover 20 such as inclining when the upper cover 20 is positioned with respect to the body case 10 by the two engaging portions 23A.

When the fitting proceeds and the projection 24 of the engaging portion 23 and the projection 16 of the engaged portion 15 are engaged with each other (see FIGS. 5 and 6), the assembly of the body case 10 and the upper cover 20 is completed. Engagements between the projections 24 of the plurality of (eight) engaging portions 23 and the respective projections 16 of the plurality of (eight) engaged portions 15 are completed at the same time. In the state in which the assembly of the body case 10 and the upper cover 20 is completed (see FIG. 3), since the projection 24 of the engaging portion 23 and the projection 16 of the engaged portion 15 are engaged with each other, the body case 10 and the upper cover 20 are prevented from being separated in the upper-lower direction.

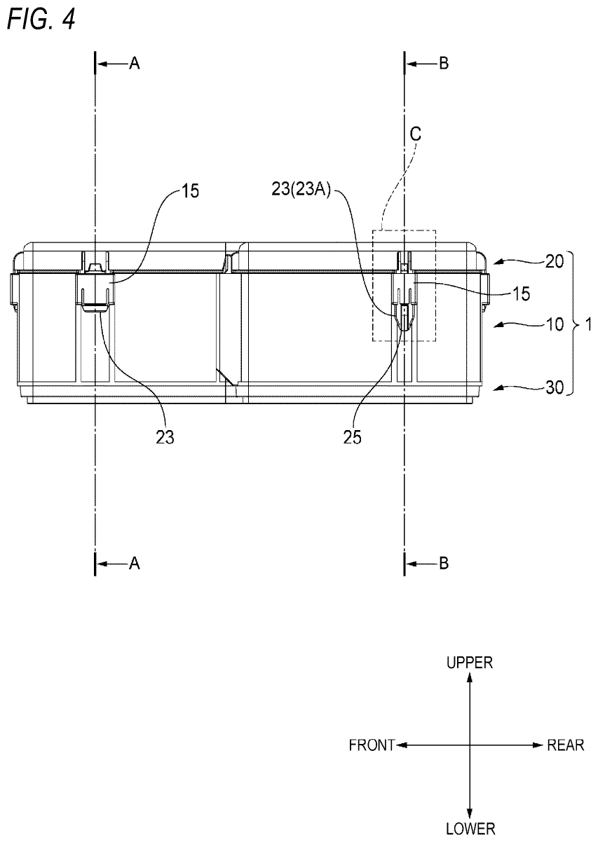

As shown in FIGS. 4 and 7, in the state in which the assembly of the body case 10 and the upper cover 20 is completed, the extending portion 25 of one of the engaging portion 23A passes through the locking hole of the corresponding engaged portion 15 and is located lower than the engaged portion 15. Therefore, the groove portion 25a that is provided on the outer surface of the extending portion 25 and that extends in the upper-lower direction is exposed to the outside. When the engagement between the engaging portion 23A and the engaged portion 15 is released, a distal end of a rod-shaped tool (not shown) that releases the engagement is slid on a bottom surface of the groove portion 25a from a lower position to an upper position, so that the distal end of the tool can be naturally guided toward a lower end edge of the outer one of the inner wall surfaces that define the locking hole of the engaged portion 15. In a state in which the distal end of the tool is inserted into the lower end edge of the inner wall surface, a proximal end side of the tool is inclined in a direction away from the body case 10. As a result, according to a principle of a lever, the projection 16 provided on the inner wall surface can be moved outward relative to the projection 24 provided on the engaging portion 23A, and the engagement between the projection 24 and the projection 16 (that is, the engagement between the engaging portion 23A and the engaged portion 15) can be released.

### Operation and Effect

As described above, according to the box-shaped body 1 according to the present embodiment, the engaging portion 23A having a length longer in the upper-lower direction is guided by the guide portion 17 of the engaged portion 15 prior to the other engaging portions 23. Accordingly, the assembly operation becomes easier and the operability of the assembly operation can be improved by first positioning the upper cover 20 with respect to the body case 10 by the engaging portions 23A having the longer length.

The two engaging portions 23A having the longer length are provided on the two surfaces of the upper cover 20 which have the different surface directions. Accordingly, it is possible to prevent misalignment of the upper cover 20 such as inclining when the upper cover 20 is positioned with respect to the body case 10 by the engaging portions 23 A having the longer length.

By guiding the tool that releases the engagement in the groove portion 25a provided in the engaging portion 23A, the operability of the operation for releasing the engagement can be improved.

When the assembly of the body case 10 and the upper cover 20 is completed, the projections 24 of the plurality of engaging portions 23 and the projections 16 of the plurality of engaged portions 15 are engaged respectively. Accordingly, even when the engaging portions 23 A having the length different from those of the other engaging portions 23 are provided, all the engaging portions 23 and the engaged portions 15 are in an engaged state after the assembly, and thus the body case 10 and the upper cover 20 can be firmly assembled.

### Other Embodiments

The present disclosure is not limited to the embodiment described above and various modifications can be adopted within the scope of the present disclosure. For example, the present disclosure is not limited to the embodiment described above, and modifications, improvements, and the like can be appropriately made. In addition, materials, shapes, sizes, numbers, arrangement positions, and the like of components in the embodiment described above are freely selected and are not limited as long as the present disclosure can be implemented.

For example, in the embodiment described above, among the plurality of (eight) engaging portions 23, two engaging portions 23 A have the length longer than those of the other engaging portions 23 in the upper-lower direction. In contrast, among the plurality of (eight) engaging portions 23, one engaging portion 23A or three or more engaging portions 23A may have a length longer than those of the other engaging portions 23 in the upper-lower direction.

Here, the features of the box-shaped body 1 according to the present disclosure described above are briefly summarized and listed in the following [1] to [4].

[1] The box-shaped body (1) including: the case (10) having the tubular peripheral wall (11); and the cover (20) assembled to the peripheral wall (11) to cover an opening end of the case (10), in which
the cover (20) includes the plurality of engaging portions (23) extending in an attachment direction in which the cover (20) is attached to the case (10),
the case (10) includes the plurality of engaged portions (15) configured to be engaged with the engaging portions (23), respectively,
each of the plurality of engaged portions (15) includes the guide portion (17) configured to guide the engaging portion (23) toward the engaged structure (16) configured to be engaged with the engaging portion (23), and
at least one (23A) of the plurality of engaging portions (23) has a length longer than a length of another engaging portion (23) in the attachment direction, and is guided by the guide portion (17) of the engaged portion (15) prior to the other engaging portion (23) when the case (10) and the cover (20) are assembled.

According to the box-shaped body having the configuration of the above [1], the engaging portion having the longer length in the attachment direction among the plurality of engaging portions is guided by the guide portion of the corresponding engaged portion prior to the other engaging portion. Accordingly, after the engaging portion having the longer length is positioned with respect to the engaged portion of the case, the assembly operation can be performed such that the other engaging portion is brought close to the engaged portion of the case. From a viewpoint of improving operability, it is preferable that the engaging portion having the longer length is disposed at a position that is easily seen by an operator. Therefore, the assembly operation becomes easier and the operability of the assembly operation can be improved compared to a case in which all the engaging portions are assembled while being simultaneously positioned.

[2] The box-shaped body (1) according to claim 1, in which
at least two (23A) of the plurality of engaging portions (23) have a length longer than a length of another engaging portion (23) in the attachment direction,
a part of the at least two engaging portions (23A) is provided to extend from a predetermined surface of the cover (20), and
the other part of the at least two engaging portions (23A) is provided on another surface of the cover (20) which has a surface direction different from a surface direction of the predetermined surface.

According to the box-shaped body having the configuration of the above [2], the part of the engaging portions having the longer length is provided to extend from the predetermined surface of the cover, and the other part of the engaging portions having the longer length is provided on the other surface of the cover which has the surface direction different from the surface direction of the predetermined surface. Accordingly, it is possible to prevent the misalignment of the cover such as inclining when the cover is positioned with respect to the case by the engaging portions having the longer length.

[3] The box-shaped body (1) according to claim 1, in which
the at least one (23A) of the engaging portions (23) has the groove portion (25a) configured to guide a tool that releases engagement between the engaging portion (23) and the engaged portion (15).

According to the box-shaped body having the configuration of the above [3], by guiding the tool that releases the engagement in the groove portion provided in the engaging portion, the operability of the operation for releasing the engagement can be improved.

[4] The box-shaped body (1) according to claim 1, in which
when assembly of the case (10) and the cover (20) is completed, the plurality of engaging portions (23) and the plurality of engaged portions (15) are engaged respectively.

According to the box-shaped body having the configuration of the above [4], when the assembly of the case and the cover is completed, the plurality of engaging portions and the plurality of engaged portions are engaged respectively. Accordingly, even when the engaging portion having the length different from that of the other engaging portion is provided, all the engaging portions and the engaged portions are in an engaged state after the assembly, and thus the case and the cover can be firmly assembled.

1. A box-shaped body comprising:
a case having a tubular peripheral wall; and
a cover assembled to the peripheral wall to cover an opening end of the case, wherein:
the cover includes a plurality of engaging portions extending in an attachment direction in which the cover is attached to the case;
the case includes a plurality of engaged portions configured to be engaged with the engaging portions, respectively;
each of the plurality of engaged portions includes a guide portion configured to guide the engaging portion toward an engaged structure configured to be engaged with the engaging portion; and
at least one of the plurality of engaging portions has a length longer than a length of another engaging portion in the attachment direction, and is guided by the guide portion of the engaged portion prior to the other engaging portion when the case and the cover are assembled.

2. The box-shaped body according to claim 1, wherein:
at least two of the plurality of engaging portions have a length longer than a length of another engaging portion in the attachment direction;
a part of the at least two engaging portions is provided to extend from a predetermined surface of the cover; and
the other part of the at least two engaging portions is provided on another surface of the cover which has a surface direction different from a surface direction of the predetermined surface.

3. The box-shaped body according to claim 1, wherein
the at least one of the engaging portions has a groove portion configured to guide a tool that releases engagement between the engaging portion and the engaged portion.

4. The box-shaped body according to claim 1, wherein
when assembly of the case and the cover is completed, the plurality of engaging portions and the plurality of engaged portions are engaged respectively.
